(19) United States
(12) Patent Application Publication
(10) Pub. No.: US 2026/0221326 A1
(43) Pub. Date: Jul. 30, 2026

(54) DEMAGNETIZATION OF WORKING-CHANNEL TOOLS IN AN ELECTROMAGNETICALLY TRACKED ENDOSCOPE

(71) Applicant: Magnisity Ltd., Hod-HaSharon (IL)

(72) Inventors: Benjamin GREENBURG, Hod-HaSharon (IL); Ron BARAK, Tel-Aviv (IL); Dror GARDOSH, Rishon LeTsiyon (IL)

(73) Assignee: Magnisity Ltd., Hod-HaSharon (IL)

(21) Appl. No.: 19/143,475

(22) PCT Filed: Dec. 27, 2023
(86) PCT No.: PCT/IL2023/051320

§ 371 Date: Jun. 26, 2025

Related U.S. Application Data
(60) Provisional application No. 63/435,344, filed on Dec. 27, 2022.
(60) Provisional application No. 63/468,275, filed on May 23, 2023.

(51) Int. Cl. H01F 13/00; G01R 33/12; G02B 23/24; H01F 7/06; H01F 7/18

(52) U.S. Cl. CPC H01F 13/006; G01R 33/1215; G02B 23/2476; H01F 7/064; H01F 7/1844

(57) ABSTRACT

The present invention discloses devices and methods for demagnetization of working-channel tools for use in an electromagnetically (EM) tracked endoscope and demagnetization of the EM tracked endoscopes themselves.

### RELATED APPLICATION/S

This application claims the benefit of priority of U.S. Provisional Ser. No. 63/435,344 filed on 27 Dec. 2022 and of U.S. Provisional Ser. No. 63/468,275 filed on 23 May 2023, the contents of which are incorporated herein by reference in their entirety.

### FIELD AND BACKGROUND OF THE INVENTION

The present invention, in some embodiments thereof, relates to devices and methods for demagnetization (also referred to as degaussing) of working-channel tools (also referred as working-channel instruments) and/or endoscopes and, more particularly, but not exclusively, to devices and methods for demagnetization of working-channel tools for use in an electromagnetically (EM) tracked endoscope and the EM tracked endoscopes themselves.

Certain Electromagnetic (EM) tracking systems use magnetometers, for example DC magnetometers, to sense low-frequency (for example, lower than 500 Hz, or lower than 1 kHz, or lower than 10 kHz, or lower than 100 kHz) EM fields for position and orientation tracking. One application of such tracking systems is for EM shape sensing of a medical device, such as a fully position and shape tracked endoscope.

An endoscope usually contains a working channel (for example, a 2.1 mm diameter working channel) through which certain clinical tools can be inserted to interact with a tissue at the distal end of the endoscope. Such tools may be for example: biopsy tools (such as forceps, needles, cytology brushes); endoluminal ultrasound devices (such as Radial probe endobronchial ultrasound (REBUS), Intravascular ultrasound (IVUS)); other endoluminal imaging (such as OCT and spectroscopy devices); ablation devices (such as RF probes, Microwave probes, cryoablation devices, drug delivery needles and probes, brachytherapy devices and seeds, laser and light fiber optics); stents and stent placement tools; clot and foreign-object retrieval tools (such as mechanical baskets, electronic devices, suction microcatheters); embolization devices (such as coils, catheters, and aneurism management devices); fiducials and their placement mechanisms; flexible endoluminal surgical tools; Electrocautery or any other cutting devices, lithotripsy and other types of therapeutic ultrasound devices.

A typical workflow of such endoscopes is as follows: (a) navigating the endoscope to a certain position of interest inside an organ (for example, to the center of a lesion inside the lungs)—this can be done based on guidance from an EM navigation system; (b) inserting a clinical tool for biopsy or localized treatment through the endoscope's working channel; (c) interacting with the tissue (for biopsy/treatment), then extract tool; (d) continuing with navigation as needed; and (e) removing the endoscope and complete procedure.

Additional background art includes U.S. Patent Application Publication No. US20220175468A1 disclosing a system for magnetic tracking of a flexible catheter device or another flexible elongated device, the system comprising: at least one generator, each configured to generate an alternating magnetic field wherein each generated magnetic field has a determined source amplitude and frequency; a device comprising: a flexible tube; a plurality of sensors, the sensors are located along the flexible tube, each configured to communicate sensed values of a local magnetic field, wherein the sensed values are at least partially due to the generated magnetic field; and a host server configured to: receive the sensed local magnetic field values from the corresponding sensors; and calculate, based on the magnetic field values and the determined source amplitude and frequency, a localization of the flexible tube, wherein the host server is optionally included in a controller of the sensors.

### SUMMARY OF THE INVENTION

Following is a non-exclusive list including some examples of embodiments of the invention. The invention also includes embodiments which include fewer than all the features in an example and embodiments using features from multiple examples, also if not expressly listed below.

Example 1. A device configured for demagnetizing a tool adapted to be inserted in a working channel of an endoscope, the device comprising:
a. a body comprising an orifice; and
b. an electromagnet component positioned at a proximity to said orifice.

Example 2. The device according to example 1, further comprising circuitry configured for generating a magnetic field by said electromagnet component.

Example 3. The device according to example lor example 2, wherein said body further comprises a handle.

Example 4. The device according to any one of examples 1-3, wherein said orifice is sized and shaped for receiving therein said working channel of said endoscope.

Example 5. The device according to any one of examples 1-4, wherein said electromagnet component comprises a motor and a rotating permanent magnet attached to said motor.

Example 6. The device according to any one of examples 1-5, wherein said electromagnet component is configured for generating a demagnetization electromagnetic field frequency of 10 kHz or below.

Example 7. The device according to any one of examples 1-6, wherein said electromagnet component comprises one or more electromagnetic coils.

Example 8. The device according to any one of examples 1-7, wherein said electromagnet component is positioned parallel and/or around to said orifice.

Example 9. The device according to any one of examples 1-8, wherein said electromagnet component is positioned perpendicular to said orifice.

Example 10. The device according to any one of examples 1-9, wherein said electromagnet component is configured for generating a magnetic field having an amplitude of about 100 mT or below, 1 T or below, or 10 T or below.

Example 11. The device according to any one of examples 1-10, wherein said device further comprises at least one sensor configured for sensing a magnetic field of said tool.

Example 12. The device according to any one of examples 1-11, wherein said at least one sensor is a magnetometer sensor.

Example 13. The device according to any one of examples 1-12, wherein said at least one sensor is positioned at a proximity of said orifice.

Example 14. The device according to any one of examples 1-13, wherein said device further comprises an indicator.

Example 15. The device according to any one of examples 1-14, wherein said circuitry is further configured for activating said indicator.

Example 16. The device according to any one of examples 1-15, wherein said indicator is configured for indicating whether a demagnetization process was successful or not.

Example 17. The device according to any one of examples 1-16, further comprising one or more motors configured for engaging said tool and further configured for moving said tool within said orifice during a demagnetization process.

Example 18. The device according to any one of examples 1-17, wherein said circuitry is further configured for controlling said one or more motors.

Example 19. The device according to any one of examples 1-18, wherein said device further comprises a shutter/valve at said orifice and configured for engaging said tool.

Example 20. The device according to any one of examples 1-19, wherein said device further comprises at least one additional sensor configured for sensing a magnetic field of said tool after said tool has passed through said electromagnet component.

Example 21. The device according to any one of examples 1-20, wherein the demagnetization electromagnet configuration includes a set of small permanent magnets positioned in alternating polarity, or oriented similarly relative to the axis of the inserted tool, or aligned with the axis of the inserted tool.

Example 22. A method of demagnetizing a tool adapted to be inserted in a working channel of an endoscope, the method comprising passing said tool through a demagnetizer.

Example 23. The method according to example 22, further comprising activating said demagnetizer while passing said tool through an orifice in said demagnetizer.

Example 24. The method according to example 22 or example 23, wherein said activating said demagnetizer is performed while inserting said tool in said working channel.

Example 25. The method according to any one of examples 22-24, wherein said activating said demagnetizer comprises applying a strong alternating magnetic field along said tool.

Example 26. The method according to any one of examples 22-25, further comprising assessing whether enough segments of said tool have been demagnetized.

Example 27. The method according to any one of examples 22-26, wherein if an answer is NO, then the method further comprises re-passing said tool through said demagnetizer.

Example 28. The method according to any one of examples 22-27, wherein if an answer is YES, then the method ends.

Example 29. A surgical device comprising:
a. a handle or an interface;
b. a tube defining a working channel;
c. an opening in said handle or interface sized and shaped for inserting a tool within said working channel; and
d. a demagnetization electromagnet component positioned at a proximity to said opening.

Example 30. The device according to example 29, further comprising circuitry configured for generating a magnetic field by said electromagnet component.

Example 31. The device according to example 29 or example 30, wherein said opening is sized and shaped for receiving therein said working channel of said surgical device.

Example 32. The device according to any one of examples 29-31, wherein said electromagnet component comprises a motor and a rotating permanent magnet attached to said motor.

Example 33. The device according to any one of examples 29-32, wherein said electromagnet component is configured for generating a demagnetization frequency of 10 kHz or below.

Example 34. The device according to any one of examples 29-33, wherein said electromagnet component comprises one or more electromagnetic coils.

Example 35. The device according to any one of examples 29-34, wherein said electromagnet component is positioned parallel and/or around to said opening.

Example 36. The device according to any one of examples 29-35, wherein said electromagnet component is positioned perpendicular to said opening.

Example 37. The device according to any one of examples 29-36, wherein said electromagnet component is configured for generating a magnetic field having an amplitude of about 100 mT or below, 1 T or below, or 10 T or below.

Example 38. The device according to any one of examples 29-37, wherein said device further comprises at least one sensor configured for sensing a magnetic field of said tool.

Example 39. The device according to any one of examples 29-38, wherein said at least one sensor is a magnetometer sensor.

Example 40. The device according to any one of examples 29-39, wherein said at least one sensor is positioned at a proximity of said opening.

Example 41. The device according to any one of examples 29-40, wherein said device further comprises an indicator.

Example 42. The device according to any one of examples 29-41, wherein said circuitry is further configured for activating said indicator.

Example 43. The device according to any one of examples 29-42, wherein said indicator is configured for indicating whether a demagnetization process was successful or not.

Example 44. The device according to any one of examples 29-43, further comprising one or more motors configured for moving said tool and further configured for moving said tool within said opening during a demagnetization process.

Example 45. The device according to any one of examples 29-44, wherein said circuitry is further configured for controlling said one or more motors.

Example 46. The device according to any one of examples 29-45, wherein said device further comprises a shutter/valve at said opening and configured for engaging said tool.

Example 47. The device according to any one of examples 29-46, wherein said device further comprises at least one additional sensor configured for sensing a magnetic field of said tool after said tool has passed through said electromagnet component.

Example 48. The device according to any one of examples 29-47, wherein the demagnetization electromagnet configuration includes a set of small permanent magnets positioned in alternating polarity, or oriented similarly relative to the axis of the inserted tool, or aligned with the axis of the inserted tool.

Example 49. A mounting interface configured for mounting an interventional device onto a surgical robotic system comprising:
a. an opening sized and shaped for inserting a tool within a working channel of said interventional device; and
b. an electromagnet component positioned at a proximity to said opening configured for demagnetizing said tool.

Example 50. The mounting interface according to example 49, comprised in a robotic endoscopic system, the robotic endoscopic system comprises a controller and/or an electrical current-driving mechanism to generate a magnetic field by said demagnetization configuration.

Example 51. The mounting interface according to example 49 or example 50, comprised in the interventional device, configured to be electrically connected to an external controller and/or an electrical current-driving mechanism to generate a magnetic field by said demagnetization configuration.

Example 52. The mounting interface according to any one of examples 49-51, comprising a magnetometer sensor at proximity to said opening, the sensor is configured to sense if demagnetization of a tool is required, wherein the demagnetization configuration is configured to be activated based on the sensor reading.

Example 53. The mounting interface according to any one of examples 49-52, comprising a magnetometer sensor at proximity to said opening, the sensor is configured to be used as feedback for demagnetization configuration.

Example 54. The mounting interface according to any one of examples 49-53, wherein the sensor reading is communicated to a controller and/or an electrical current-driving mechanism, which determines based on the sensor reading whether to generate a magnetic field by said demagnetization configuration.

Example 55. The mounting interface according to any one of examples 49-54, wherein the demagnetization electromagnet configuration includes a set of small permanent magnets positioned in alternating polarity, or oriented similarly relative to the axis of the inserted tool, or aligned with the axis of the inserted tool.

Example 56. The mounting interface according to any one of examples 49-55, wherein the demagnetization electromagnet configuration includes a rotating magnet.

Example 57. An interventional device, comprising:
a. an elongated body;
b. a plurality of sensors positioned on said elongated body; and
c. a plurality of demagnetization components located adjacent or below said plurality of sensors.

Example 58. The device according to example 57, wherein said demagnetization components are EM coils.

Example 59. The device according to example 57 or example 58, wherein said EM coils are wrapped around a working channel.

Example 60. The device according to any one of examples 57-59, wherein said EM coils are operated by external controller.

Example 61. The device according to any one of examples 57-60, wherein said EM coils are positioned near said sensors.

Example 62. The device according to any one of examples 57-61, wherein said EM coils are wrapped around said sensors, perpendicular to said working channel.

Example 63. The device according to any one of examples 57-62, wherein said sensors are used to detect magnetization of the device and/or of introduced working channel tools.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

As will be appreciated by one skilled in the art, some embodiments of the present invention may be embodied as a system, method or computer program product. Accordingly, some embodiments of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, some embodiments of the present invention may take the form of a computer program product embodied in one or more computer readable medium(s) having computer readable program code embodied thereon. Implementation of the method and/or system of some embodiments of the invention can involve performing and/or completing selected tasks manually, automatically, or a combination thereof. Moreover, according to actual instrumentation and equipment of some embodiments of the method and/or system of the invention, several selected tasks could be implemented by hardware, by software or by firmware and/or by a combination thereof, e.g., using an operating system.

For example, hardware for performing selected tasks according to some embodiments of the invention could be implemented as a chip or a circuit. As software, selected tasks according to some embodiments of the invention could be implemented as a plurality of software instructions being executed by a computer using any suitable operating system. In an exemplary embodiment of the invention, one or more tasks according to some exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

Any combination of one or more computer readable medium(s) may be utilized for some embodiments of the invention. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium and/or data used thereby may be transmitted using any appropriate medium, including but not limited to wireless, wireline, optical fiber cable, RF, etc., or any suitable combination of the foregoing.

Computer program code for carrying out operations for some embodiments of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Some embodiments of the present invention may be described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Some of the methods described herein are generally designed only for use by a computer, and may not be feasible or practical for performing purely manually, by a human expert. A human expert who wanted to manually perform similar tasks might be expected to use completely different methods, e.g., making use of expert knowledge and/or the pattern recognition capabilities of the human brain, which would be vastly more efficient than manually going through the steps of the methods described herein.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic representation of an exemplary endoscopic surgical system;

FIG. 2 is a schematic representation of an exemplary external demagnetization device for a working-channel tool or an endoscopic device, according to some embodiments of the invention;

FIG. 3 is a schematic representation of an exemplary endoscopic device, which includes a demagnetization electromagnet component, according to some embodiments of the invention;

FIG. 4 is a schematic representation of an exemplary robotic endoscopic system, which includes a demagnetization electromagnet component, according to some embodiments of the invention;

FIG. 5 is a schematic representation of an exemplary endoscopic device comprising internal demagnetization devices, according to some embodiments of the invention;

FIG. 6A-B are schematic representations of exemplary demagnetization electromagnet configurations (also referred herein as electromagnet configurations) 600a and 600b respectively, according to some embodiments of the invention; and

FIG. 7 is a flowchart of an exemplary method of demagnetizing a tool according to some embodiments of the invention.

### DESCRIPTION OF SPECIFIC EMBODIMENTS OF THE INVENTION

The present invention, in some embodiments thereof, relates to devices and methods for demagnetization of working-channel tools and, more particularly, but not exclusively, to devices and methods for demagnetization of working-channel tools for use in an electromagnetically (EM) tracked endoscope.

### Overview

An aspect of some embodiments of the invention relates to demagnetizing endoscopic devices and tools used within the endoscopic devices, where electromagnetic fields are used to track and monitor the endoscopic devices. In some embodiments, a dedicated demagnetization device is used on the endoscopic devices and/or the tools. In some embodiments, demagnetization of the tools is done before being inserted within the endoscopic devices. In some embodiments, dedicated demagnetization devices for tools are incorporated within the endoscopic devices (either manual endoscopic devices or dedicated robotic endoscopic systems), meaning the demagnetization devices are an integral part of the endoscopic devices/systems and/or are an add-on to existing devices/systems. In some embodiments, endoscopic systems comprise robotic means to move the endoscope and/or the tools, which can then be used to move the tools thorough the demagnetization devices. In some embodiments, a potential advantage of demagnetizing the tools is that it potentially avoids magnetic interference (such as undesirable bias or saturation or distorted readings) on the sensors tracking the endoscopic device. In some embodiments, demagnetization devices are incorporated in the handle or interface (in the case of a robotic endoscope) of the endoscopic device, and tools that are meant to be used within the working channel of the endoscopic device are passed through the demagnetization device in the handle. In some embodiments, demagnetization devices are positioned within the endoscopic device, under or adjacent the location of the sensors used for position and orientation tracking of the endoscopic device. In some embodiments, in this case, the demagnetization devices are configured to demagnetize the endoscopic device and/or any tool passing within the working channel in the areas where the sensors are.

An aspect of some embodiments of the invention relate to methods and devices for demagnetization of endoscopic devices and tools used with endoscopic devices that may have tendency to become magnetized during manufacturing, packaging, handling and/or usage of the endoscopic devices/tools. For example, endoscopic devices/tools made of ferromagnetic materials may possess a remnant magnetic field. In some embodiments, the demagnetization of the tools may be performed, for example, in preparation to insertion of such tools into a working channel, for example, of an electromagnetically tracked endoscopic device. In some embodiments, electromagnetic sensors inside the device may comprise one or more magnetometers (for example, DC magnetometers, digital magnetometers, coil-based magnetometers, or others which can be based on hall-effect, magneto-resistive effect, magneto-inductive effect, Faraday's law or any other suitable magnetic sensing method), located in close proximity inside, outside or around the working channel. In some embodiments, tools which are introduced into a working channel of an electromagnetically tracked endoscope device might get undesirably magnetized in the manufacturing process as well as during handling and use of the tools due to multiple causes (for example, in the presence of strong magnetic fields, electrical currents, heat, stress etc.) and may therefore possess a remnant magnetic field. In some embodiments, this may cause distorted readings in the electromagnetic sensors on the device. For example, the proximity of magnetized tools, as the tools are introduced into the working channel, may cause saturation in DC-type or AC-type EM sensors, which may only operate linearly at a certain dynamic range (for example, ±1000 uT or ±4000 uT or ±10000 uT). For example, some DC-type EM sensors are digital and may operate only within a dynamic range of ±1000 uT, beyond which they are saturated. Some AC-type EM sensors may comprise one or more EM coils wrapped around an EM core (such as Ferrite) which may saturate at certain magnetic biases such that the sensor is no longer linear, which may cause distortion. In some embodiments, in AC-type EM sensors, such as coil-based sensors which may be based on Faraday's law of induction, the presence of magnetized tool may cause distorted readings due to dynamic movement of the tool relative to the EM sensor, which may induce distorting voltage in the EM sensing coils (similarly to moving a permanent magnet near EM coil-based sensors). More generally, the movement of magnetized tool near an EM sensor may be erroneously interpreted in the sensor readings as an alternating magnetic field at a same or similar frequency (low-frequency or high-frequency) as the fields generated by the electromagnetic fields generator, which can distort the tracking of that distorted sensor. This is true both in the case of DC-type and AC-type EM sensors. In some embodiments, it is therefore desirable to demagnetize the working-channel tools, for enabling successful EM tracking of the tracked device with inserted working channel tools, minimizing the magnetic interference (e.g., distortion effects) of static and moving magnetized tools. In some embodiments, demagnetization devices can be a separate device from the endoscopic device and/or the tools, in which case, the endoscopic device and/or the tools are demagnetized by passing them through or in proximity of the demagnetization device. In some embodiments, demagnetization devices can be an integral part of the endoscopic devices, for example, located at the handle or interface (in the case of a robotic endoscope) where the tools are demagnetized when inserted into the working channel of the endoscopic device; or for example, demagnetization devices can be located under or adjacent the electromagnetic sensors inside the endoscopic device (for example one or more magnetometers), in which case the demagnetization devices demagnetize both the areas of the endoscope where the sensors are positioned and of the tools passing through the working channel in the vicinity of the sensors.

An aspect of some embodiments of the invention relate to a device for demagnetization of surgical or endoscopic working channel tools, the device comprising: a body having a handle or an interface and an orifice; a demagnetization electromagnet configuration (also referred herein as electromagnet configuration) positioned at proximity to said orifice, so that a working channel tool can be inserted at proximity to the electromagnet(s); and an optional controller to generate alternating magnetic field by said electromagnet(s).

An aspect of some embodiments of the invention relate to a surgical or endoscopic device comprising: a handle or an interface; a working channel; an opening in the handle or interface, enabling insertion of working channel tools into the working channel; an electromagnet configuration positioned at proximity to said opening, so that a working channel tool can be inserted at proximity to the electromagnet; and an optional controller to generate magnetic field by said electromagnet(s).

An aspect of some embodiments of the invention relate to a device for demagnetization of surgical working channel tools, the device comprising a body having a handle or an interface and an orifice; an electromagnet configuration positioned at proximity to said orifice, so that a working channel tool can be inserted at proximity to the electromagnet configuration; and an optional controller to generate a magnetic field by said electromagnet.

An aspect of some embodiments of the invention relate to a surgical device comprising a handle or an interface; a working channel; an opening in the handle or interface, enabling insertion of working channel tools into the working channel; an electromagnet configuration positioned at proximity to said opening, so that a working channel tool can be inserted at proximity to the electromagnet configuration; and an optional controller to generate a magnetic field by said electromagnet.

An aspect of some embodiments of the invention relate to a mounting interface to mount an interventional device to a surgical robotic system, the interface comprising an opening for inserting a tool into a working channel of the device; and a demagnetization electromagnet configuration, positioned at proximity to said opening, configured to demagnetize a tool when inserted via the opening. In some embodiments, the mounting interface is part of a robotic endoscopic system. In some embodiments, the robotic endoscopic system comprises a controller and/or an electrical current-driving mechanism to generate a magnetic field by said demagnetization configuration. In some embodiments, the mounting interface is configured to be electrically connected to an external controller and/or an electrical current-driving mechanism to generate a magnetic field by said demagnetization configuration. In some embodiments, the mounting interface comprises a magnetometer sensor at proximity to an opening. In some embodiments, the sensor is configured to sense if demagnetization of a tool is required. In some embodiments, the demagnetization device is configured to be activated based on the sensor reading.

In some embodiments, the magnetometer sensor is configured to be used as feedback for demagnetization device. In some embodiments, the sensor reading is in communication with a controller and/or an electrical current-driving mechanism, which determines based on the sensor reading whether to generate a magnetic field by said demagnetization configuration. In some embodiments, the demagnetization device includes a set of small permanent magnets positioned in alternating polarity, or oriented similarly relative to the axis of the inserted tool, or aligned with the axis of the inserted tool. In some embodiments, the demagnetization device includes a rotating magnet.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

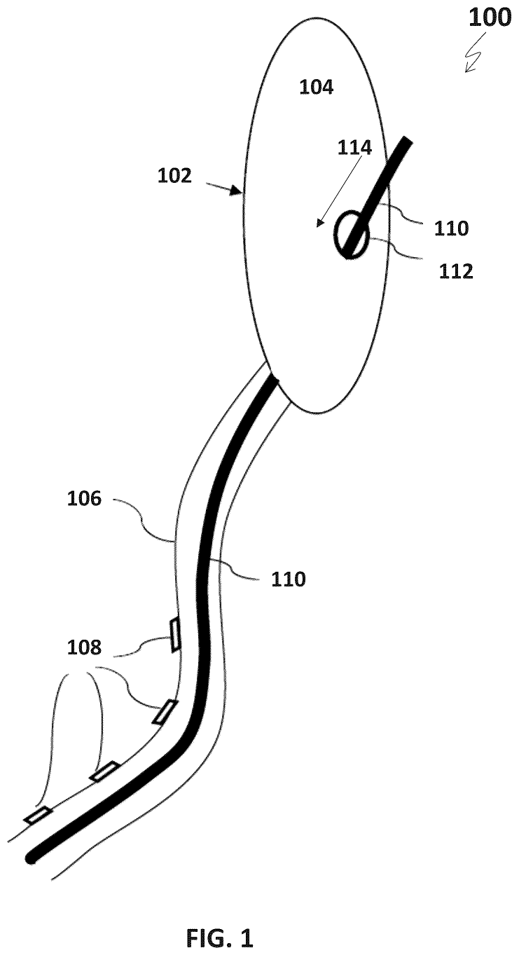

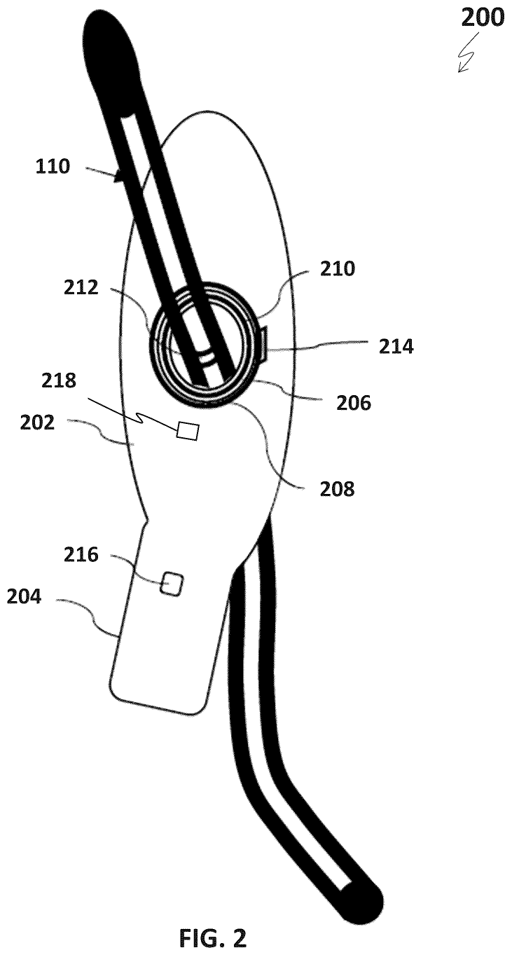

For purposes of better understanding some embodiments of the present invention, as illustrated in FIGS. 2-5a-b of the drawings, reference is first made to the construction and operation of an endoscopic surgical system 100, as illustrated in FIG. 1.

In some embodiments, an exemplary system 100 includes an EM fully shape tracked endoscope 102, which may comprise a handle or an interface 104, a working channel 106, and one or more EM sensors 108, for example, DC magnetometers, placed at a proximity outside of working channel 106. In some embodiments, the EM sensors 108 are assembled, for example, on a Flexible Printed Circuit (FPC) and wrapped around the working channel 106. For example, each of the sensors 108 is positioned at distance less than 1 mm from the boundary, e.g., the external diameter, of the working channel 106. In some embodiments, the sensors 108 operate within a certain dynamic range (for example, ±1000 uT or ±4000 uT or ±10000 uT). In this case, to avoid potential saturation of the sensors 108 and to allow for a wide range of magnetic measurements, it may be advisable not to expose them to strong magnetic fields (for example, stronger than 500 uT).

In some embodiments, the sensors 108 are used to detect the magnetization of the areas of the endoscope where the sensors are positioned as well as of tools entering the working channel 106 (see below for more information). In some embodiments, by detecting strong DC magnetic fields, for example, larger than 500 uT or such that the sensors 108 are saturated, the sensors 108 are configured to indicate to a controller that they are saturated, or near saturation, which may indicate that the corresponding areas of the endoscope are magnetized or that a tool inserted in the working channel 106 is magnetized (possess significant remnant magnetic field). In some embodiments, this mechanism of detection of saturation can be used in addition or alternatively to the detection mechanism of one or more dedicated magnetometers 214/218 as shown for example in FIG. 2.

In some embodiments, the system 100 further includes a tool 110, which may be introducible into the working channel 106, for example in order to perform a certain procedure, for example, at the distal end of working channel 106. In some embodiments, the tool 110 is inserted (schematically shown by arrow 114) into the working channel 106 via an opening 112 located at the handle or interface 104. In some embodiments, the tool 110 may be made of metallic materials, such as stainless steel. Some stainless steels are known to be magnetic (for example, Ferritic stainless steels, and most Martensitic stainless steels, and some Austenitic stainless steels). These steels can get undesirably magnetized in the manufacturing process of the tool 110 as well as during handling and use of the tool 110 due to multiple reasons (for example, in the presence of strong magnetic fields, electrical currents, heat, stress etc.). When a magnetized tool 110 is inserted into the working channel 104 of an EM tracked endoscope 102, a magnetic field of the tool 110 may be sensed by the sensors 108. Due to the close proximity of the sensors 108 to the working channel 106 (for example, at distance less than 1 mm from the boundary of the working channel 106), and depending on the strength of the magnetization of one or more sections along the tool 110, the sensors 108 may sense a relatively strong magnetic field (for example, stronger than 500 uT) which may cause the sensors 108 to saturate, or bring the sensors 108 near saturation, or cause the readings of the sensors 108 to be distorted by the strong field, for example due to non-linearity of the EM sensor near saturation, so that they can no longer be used, or they can only be partially used, for the EM position and orientation tracking of device 102. It is therefore desirable that a tool 110 will either be non-magnetic, e.g., will not possess the ability to be magnetized, or will be fully or partially demagnetized before insertion into the working channel 106.

In some embodiments, a strong alternating magnetic field is applied along the length of tool 110 in order to fully or partially demagnetize the tool 110 prior to inserting it into the working channel 106.

For example, in some embodiments, the tool 110 is demagnetized using a strong rotating permanent magnet (such as a Neodymium rare earth magnet) attached to a DC motor or oscillator. For example, in some embodiments, the tool 110 is demagnetized using a pair (2 or more) of strong permanent magnets (such as a Neodymium rare earth magnet) with opposite poles facing the working channel and moved near and far to the working channel using a DC motor or oscillator.

### Exemplary Demagnetization Devices, Their Locations and Used Thereof

In some embodiments, demagnetization devices are divided into two main groups: demagnetization devices separated from the endoscopic devices and/or tools (referred herein as external demagnetization devices) and demagnetization devices positioned within the endoscopic devices or robotic systems used thereof (referred herein as internal demagnetization devices). In some embodiments, external demagnetization devices are used to demagnetize both the endoscopic devices and the tools used with the endoscopic devices. In some embodiments, internal demagnetization devices are configured, depending on their location, to demagnetize either the tools or both the tools and the endoscopic devices (or at least parts thereof).

In some embodiments, the endoscope may be magnetized and it may be beneficial to demagnetize it for similar purposes as the reasons mentioned above for the case of demagnetization of tool 110, such as, to potentially avoid magnetic interference (such as undesirable bias or saturation) on the sensors tracking the endoscopic device. The endoscope may be magnetized for example because it may contain ferromagnetic metals, such as certain stainless steels (similarly to the tool 110), for example, in the case of a braided shaft, or bending section which consists of metallic links or for other reasons.

### Exemplary External Demagnetization Devices

Referring now to FIG. 2, showing a schematic representation of an exemplary external demagnetization device 200 for a working-channel tool 110 or an endoscopic device 102, according to some embodiments of the invention. Same parts are provided with a same reference number, unless provided otherwise.

For example, in some embodiments, the tool 110 and/or the endoscopic device 102 are demagnetized using a pair (2 or more) of strong permanent magnets (such as a Neodymium rare earth magnet) with opposite poles facing the working channel and moved near and far to the working channel using a DC motor or oscillator.

In some embodiments, an operator holds a handle where a magnet is rotating along its axis. In some embodiments, the operator swipes the rotating or oscillating one or more magnets along the length of the endoscopic device 102 and/or along the length of the tool 110 prior to inserting the tool 110 into the working channel 106. In some embodiments, the magnet is configured for rotating or oscillating, for example, at 30 Hz (1800 RPM) or below, 60 Hz (3600 RPM) or below, 100 Hz (6000 RPM) or below, or at any other mechanically feasible rate.

In some embodiments, an exemplary external demagnetization device 200 comprises a body 202 and optionally a handle 204. In some embodiments, an exemplary external demagnetization device 200 comprises one or more electromagnetic coils or toroid or a rotating or oscillating magnet or any other suitable electromagnet 206, configured for generating a strong alternating magnetic field, for example within an orifice 208 in body 202. In some embodiments, the electromagnet 206 is wound around orifice 208. In some embodiments, the electromagnetic coils are arranged perpendicular to the orifice 208, or parallel and aside from orifice 208. In some embodiments, optionally, the electromagnet 206 is shielded by a hollow high magnetic permeability shield 210, such as, for example, a ferritic or iron shield. In some embodiments, the external demagnetization device 200 is configured for generating alternating electrical current through a wound wire of the electromagnet 206, which in turn generates an alternating magnetic field, according to Ampere's law. In some embodiments, an endoscopic device 102 and/or a tool 110 is then inserted and passed through the electromagnet 206.

In this case, the tracked length/section of the endoscope (where the magnetic sensors are located), which may be a limited range along the endoscope shaft/tube (for example, the distal 150 mm or 200 mm or 250 mm or 300 mm or longer) needs to be demagnetized. More specifically, each section near each sensing element (for example, near each magnetometer sensor) needs to be demagnetized to allow for proper tracking of each sensing element individually and for all sensors collectively.

In some embodiments, if some sensor elements are detected to be magnetized, an automatic demagnetization process of those sensor sections can be applied. In some embodiments, each sensor element contains a coil wrapped around the shaft of the endoscope which may contain a braided working channel, at that sensor section, or wrapped around the sensor itself (perpendicular to the shaft of the endoscope) or in proximity to the sensor. For example, a coil may be wrapped 1 mm, or 3 mm, or 5 mm or 10 mm before and/or after the sensor position along the endoscope's shaft. When a sensor element is detected to be magnetized, it means that the sensor section is magnetized and the coil of that section is then activated to demagnetize this section. For example, a controller can drive the magnetized section's coil with a 10 Hz, 30 Hz, 60 Hz, 100 Hz, 200 Hz, 1 kHz, 10 kHz high electrical current (as also mentioned above for the case of tool demagnetization) to demagnetize this section. The controller may do so until each sensor element does not measure a high magnetic bias (for example, higher than 500 uT), which indicates that all sensor sections are essentially demagnetized.

In some embodiments, the generated magnetic field at the center of electromagnet 206 comprises, for example, an amplitude of about 10 mT (10 milli-Tesla), about 100 mT (100 milli-Tesla), about 1 T (1 Tesla), about 10 T (10 Tesla) or of another suitable strength of magnetic field for the purpose of demagnetization. In some embodiments, while inserting endoscopic device 102 and/or the tool 110 through electromagnet 206, inserted segments 212 along endoscopic device 102 and/or the tool 110 experience a strong alternating field, which diminishes as the segment 212 is pulled or pushed from the electromagnet 206. In some embodiments, in this manner, as the endoscopic device 102 and/or the tool 110 is moved inside the orifice 208, the segments 212 along the endoscopic device 102 and/or the tool 110 are subjected to a strong alternating magnetic field with diminishing amplitude, which cause demagnetization.

In some embodiments, the frequency of the electromagnet 206 is of 10 Hz, 30 Hz, 60 Hz, 100 Hz, 200 Hz, 1 kHz, 10 kHz or any other frequency suitable for demagnetization. In some embodiments, preferably, a high frequency for the generated demagnetization field (for example, 1 kHz of higher) is used. In some embodiments, a potential advantage of using a high frequency is to enable fast demagnetization. For example, a high frequency demagnetization field enables demagnetization of the tool 110 by quickly passing the tool 110 through the electromagnet 206, enabling each segment 212 of the tool 110 to experience a strong alternating magnetic field, where contrary to this, lower frequency demagnetization fields may not suffice. For example, if the tool 110 is pushed with high speed through the demagnetization coil, for example with an exemplary velocity of 1 meter/sec, each 1 mm of the tool 110 will experience a complete period of a 1 kHz alternating demagnetization field, which may be sufficient for the full or partial demagnetization of this specific 1 mm length along the tool. Contrary to this, with a demagnetization frequency lower than 1 kHz, each 1 mm of the tool 110 will experience a subperiod of the alternating demagnetization field at a 1 meter/sec tool insertion velocity.

In some embodiments, the external demagnetization device 200 includes one or more magnetometer sensors 214 attached to the orifice 208, configured to sense the magnetic field of the endoscopic device 102 and/or the tool 110 and/or segment 212 of the endoscopic device 102 and/or the tool 110 before and/or after it passes through the electromagnet 206. In some embodiments, sensing a strong magnetic field at a certain segment 212 before it passes through electromagnet 206, will be used to indicate that demagnetization is necessary for this segment (i.e., that this segment of the device/tool is magnetized). In some embodiments, an indication is communicated to the user or to a controller. In some embodiments, the electromagnet 206 is activated, optionally automatically activated, in response to this indication. In some embodiments, sensing a strong magnetic field at a certain segment 212 after it passes through the electromagnet 206 indicates that the demagnetization process has failed for this segment (i.e., that this segment of the device/tool is still magnetized). In some embodiments, in that case, the endoscopic device 102 and/or the tool 110 is pulled back and/or reinserted into the electromagnet 206.

In some embodiments, an exemplary external demagnetization device 200 comprises one first magnetometer sensor sensing the tool 110 before passing through electromagnet 206, to assess whether a segment needs to be demagnetized, and one second magnetometer sensor 218 sensing the tool after it exits electromagnet 206, to assess whether the segment was successfully demagnetized. In some embodiments, the second sensor 218 is positioned inside the handle 204, about 2 to 3 cm after the opening 208, so after the endoscopic device 102 and/or the tool 110 passes the demagnetization electromagnet component 206, the second sensor 218 assesses whether the demagnetization process was successful.

In some embodiments, an exemplary external demagnetization device 200 comprises one or more indicators 216 configured to be activated by a controller and configured to allow indicating a user, for example by a light emitting diode (LED) or by any other suitable manner, whether the demagnetization of the endoscopic device 102 and/or tool 110 was successful, thereby providing a positive/negative feedback, during the introduction of the endoscopic device 102 and/or the tool 110 into the external demagnetization device 200. For example, a green light may indicate success while red light may indicate failure to demagnetize, in which case the endoscopic device 102 and/or the tool 110 may be passed again through the electromagnet 206. In some embodiments, the external demagnetization device 200 optionally comprises a shutter and/or a valve (not shown), which may be automatically opened and closed depending on the magnetization state of the endoscopic device 102 and/or tool 110, for example based on an indication received from the one or more sensors 214/218 and optionally shown on the indicator 216. In some embodiments, additionally or alternatively, an exemplary external demagnetization device 200 comprises one or more motors (not shown), configured for automatically move the endoscopic device 102 and/or the tool 110 through the electromagnet 206 as needed, until the endoscopic device 102 and/or the tool 110 is sufficiently demagnetized. In some embodiments, the automated moving mechanism for the endoscopic device 102 and/or the tool 110 is a semi-automated tool insertion mechanism or a fully automated robotic tool insertion mechanism as described herein.

### Exemplary Internal Demagnetization Devices

In some embodiments, as mentioned above, demagnetization devices are incorporated within the endoscopic devices and/or robotic systems used with the endoscopic devices. In some embodiments, possible internal locations for the demagnetization devices are one or more of: on a handle of an endoscopic device, on an adaptor or interface of a robotic system manipulating an endoscopic device and under or adjacent the location of the sensors used for position and orientation tracking of the endoscopic device in the endoscopic device itself.

### Exemplary Internal Demagnetization Device Located in The Handle of an Endoscopic Device

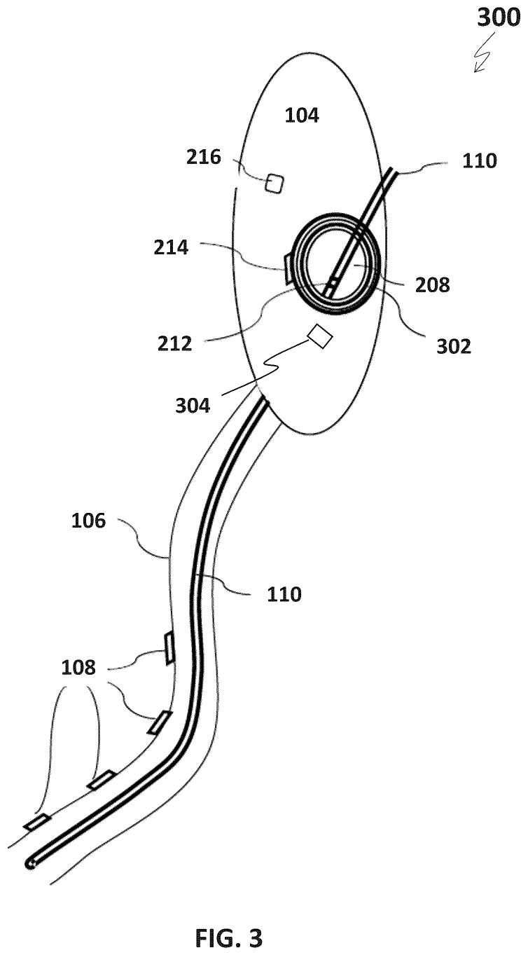

Reference is now made to FIG. 3, showing a schematic representation of an exemplary endoscopic device 300, which includes a demagnetization electromagnet component 302, according to some embodiments of the invention. In some embodiments, the demagnetization electromagnet component 302 is configured to be incorporated into and/or inside a handle 104 of the endoscope 300. The handle 104 can also be a robotic interface (in case of a robotic endoscope 400—see below). Endoscope 300 is similar to the endoscope 100 shown in FIG. 1, and same parts are provided with the same reference numbers in both Figures, where relevant. In some embodiments, as tool 110 is introduced into the endoscope 300, it passes through the working channel 106 via an opening 208 in located in the handle (or interface) 104. In some embodiments, the demagnetization electromagnet component 302 is positioned on or near, for example around, opening 208. In some embodiments, the tool 110 is demagnetized by the demagnetization electromagnet component 302, for example by using any of the methods mentioned herein. For example, in some embodiments, the tool 110 is demagnetized using a strong rotating permanent magnet (such as a Neodymium rare earth magnet) attached to a DC motor or oscillator. For example, in other embodiments, the tool 110 is demagnetized using a pair (2 or more) of strong permanent magnets (such as a Neodymium rare earth magnet) with opposite poles facing the working channel and moved near and far to the working channel using a DC motor or oscillator. Accordingly, the tool 110 is demagnetized before it is inserted into working channel 106 and/or to the proximity of EM sensors 108, for example as described with reference to FIG. 1. Accordingly, segments 212 of tool 110, which may be magnetized, are demagnetized in advance in opening 208 before reaching sensors 108.

In some embodiments, there is a second sensor 304 configured to measure the electromagnetic field of the tool after the demagnetization process, configured to assess whether the demagnetization process has been successful. In some embodiments, the second sensor 304 is positioned inside the handle 104, about 2 to 3 cm after the opening 208, so after the tool passes the demagnetization electromagnet component 302, the second sensor 304 assesses whether the demagnetization process was successful.

In some embodiments, in this case, when the demagnetization electromagnet component 302 is located at the handle 104 of the endoscopic device 300, the demagnetization process is applied only to the tools 110 used therein (and not the endoscopic device itself).

### Exemplary Internal Demagnetization Device Located in a Robotic Endoscopic System Manipulating an Endoscopic Device

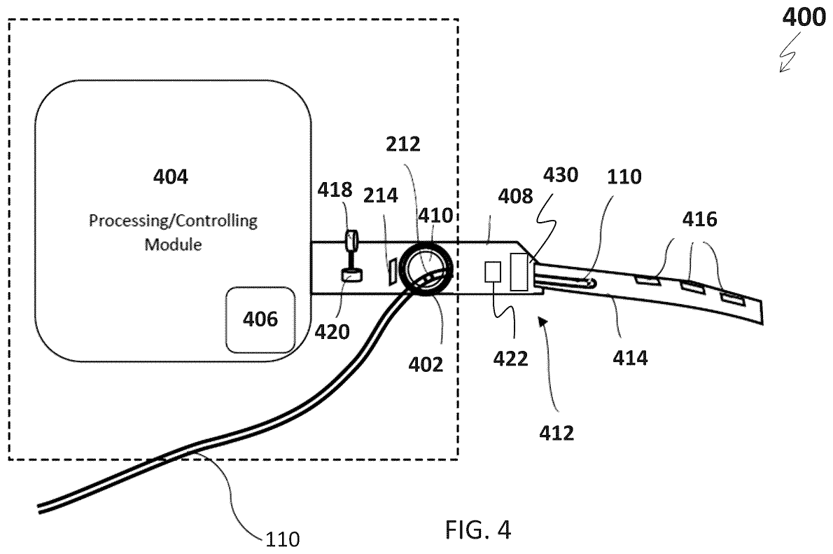

Referring now to FIG. 4, showing a schematic representation of an exemplary robotic endoscopic system 400, which includes a demagnetization electromagnet component 402, according to some embodiments of the invention. In some embodiments, the system 400 comprises one or more of a processing/controlling module 404, an optional electrical current-driving mechanism 406, an optional automatic or semi-automatic mechanical tool driving mechanism 430 (also referred herein as robotic tool insertion mechanism), an interface 408, an opening 410 and an endoscope tube or shaft 412 (referred hereinafter as “tube”) having a working channel 414 and EM sensors 416. In some embodiments, the demagnetization electromagnet component 402 is placed inside the robotic interface 408 of the robotic system 400.

In some embodiments, an additional demagnetization electromagnet component (not shown in Figure) is provided in the robotic system 400 and is configured for demagnetizing the endoscopic device itself

In some embodiments, as tool 110 is introduced into the endoscope tube 412, it passes through the working channel 414 via the opening 410 in the interface 408. In some embodiments, the demagnetization electromagnet component 402 is positioned on or near, for example around, the opening 410, thereby demagnetizing tools 110 entering the working channel 414 via opening 410.

In some embodiments, the demagnetization electromagnet component 402 is located inside interface 408, which may be part of a disposable robotic endoscope. In some embodiments, additionally or alternatively, the demagnetization electromagnet component 402 is located inside robotic endoscopic system 400, which may not be part of a disposable robotic endoscope.

In some embodiments, the tool 110 is demagnetized by the demagnetization electromagnet component 402, for example by using any of the methods mentioned herein. For example, in some embodiments, the tool 110 is demagnetized using a strong rotating permanent magnet (such as a Neodymium rare earth magnet) attached to a DC motor or oscillator. For example, in other embodiments, the tool 110 is demagnetized using a pair (2 or more) of strong permanent magnets (such as a Neodymium rare earth magnet) with opposite poles facing the working channel and moved near and far to the working channel using a DC motor or oscillator. In some embodiments, accordingly, the tool 110 is demagnetized before it is inserted into the working channel 414 and/or to the proximity of EM sensors 416, for example as described with reference to FIG. 1. Accordingly, segments 212 of tool 110, which may be magnetized, are demagnetized in advance in opening 410 before reaching sensors 416. In some embodiments, additionally or alternatively, the demagnetization electromagnet component 402 is positioned inside a robotic mount, which is part of robotic system 400. For example, interface 408 may include a robotic mount by which, for example, the endoscope tube 412 may be mounted to robotic system 400. In some embodiments, the endoscope tube 412 (which may be disposable) is mounted onto the robotic mount through the interface 408. In some embodiments, the robotic mount may contain the demagnetization electromagnet component 402, which may be positioned near opening 410 of the working channel 414 of the endoscope. In some embodiments, a potential advantage of placing the demagnetization electromagnet component 402 in a robotic reusable system (rather than in a disposable system) potentially allows using high-end, high-current demagnetization coils, for example for producing strong magnetic fields, for example stronger than 100 mT or stronger than 1 T or stronger than 10 T, for effective demagnetization of the introduced working channel tools. The demagnetization coils can potentially be driven by high-end electrical current-driving mechanism which resides in the robotic system.

In some embodiments, alternatively or additionally, the endoscope tube 412 may include the interface 408 and the demagnetization electromagnet component 402 as described above near opening 410, and the interface 408 may be used for connecting to, for example, an existing robotic system 400. In some embodiments, the robotic system 400 comprises an electrical current-driving mechanism 406, and it is configured for interfacing with the demagnetization electromagnet component 402 through the endoscope's robotic interface 408. In some embodiments, the electrical current-driving mechanism 406 is configured for generating high electrical currents through the interface 408, into the endoscope tube 412 and through the demagnetization electromagnet component 402 to generate strong demagnetization fields to demagnetize introduced working channel tools, such as tool 110.

In some embodiments, a potential advantage of placing the demagnetization electromagnet component 402 and/or the electrical current-driving mechanism 406 in a robotic system 400 and outside the endoscope tube 412 is that it can potentially reduce the costs of a robotic endoscope, for example, in the setting of a disposable robotic endoscope.

In some embodiments, device 400 may include a magnetometer sensor 214 attached to opening 410, for example to sense the magnetic field of tool 110 and/or segment 212 before and/or after it passes through the demagnetization electromagnet component 402, as previously explained. In some embodiments, as mentioned above, sensing a strong magnetic field at a certain segment 212 before it passes through the demagnetization electromagnet component 402, may indicate that demagnetization is necessary for this segment. For example, an indication may be communicated to the user or to a controller. In some embodiments, the demagnetization electromagnet component 402 may be activated in response to this indication, automatically or manually. In some embodiments, sensing a strong magnetic field at a certain segment 212 after it passes through the demagnetization electromagnet component 402 indicates that demagnetization failed for this segment. In that case, the tool 110 may be pulled back and/or reinserted into the demagnetization electromagnet component 402. In some embodiments, in the robotic case, a magnetometer sensor 214 may be placed in robotic system 400, near the mounted endoscope's working channel 414, to reduce the costs and complexity of robotic endoscope. In some embodiments, sensing of magnetized working channel tools can then take place using the magnetometer inside the robotic system and by processing module 404 which resides inside robotic system 400. In some embodiments, the robotic system 400 comprises instructions to decide whether to activate or deactivate the demagnetization electromagnet component 402, which may also reside in robotic system 400, as described above. In some embodiments, in the case of a robotic tool insertion mechanism, automatic tool insertion can be operated based on tool magnetization status as sensed by magnetometer sensor 214, as described above.

In some embodiments, there is a second magnetometer sensor 422, optionally positioned about 2 to 3 cm after the demagnetization electromagnet component 402, and configured to measure the electromagnetic field of the tool after the demagnetization process, configured to assess whether the demagnetization process has been successful.

In some embodiments, an indicator on device 400 may communicate to a controller 404 and/or to a user, for example by a light emitting diode (LED) or by any other suitable manner, whether the demagnetization of tool 110 is successful (to be used as a feedback), during the introduction of tool 100 into device 400. For example, similarly to the described with reference to FIG. 2.

In some embodiments, the robotic tool insertion mechanism 430 is configured for pushing the tool 110 through the working channel at a velocity which is suitable for demagnetization of the tool 110. In some embodiments, if a segment 212 of the tool 110 is still magnetized after passing through the electromagnet 402, as may be sensed by a magnetometer sensor 422, the robotic tool insertion mechanism is further configured for pulling the tool 110 back so the specific segment 212 that was not successfully demagnetized and would perform another passing through the electromagnet 402 until the segment 212 is sensed as demagnetized to a satisfactory degree, as may be sensed by magnetometers 214 and/or 422. In some embodiments, the electromagnet 402 is activated and deactivated based on one or more magnetic readings of the magnetometers 214 and/or 422. In some embodiments, a potential advantage of this mechanism is that the robotic tool insertion mechanism potentially ensures that the inserted tool 110 is fully or partially demagnetized.

In some embodiments, the endoscopic handle 104 or the robotic endoscope's interface 408 optionally comprises a shutter and/or a valve (not shown), which may be automatically opened and closed depending on the magnetization state of the tool 110, for example based on an indication received from the one or more sensors 214/218/422 and optionally shown on the indicator 216.

In some embodiments, for example, related to medical uses, system 400 and/or endoscope 412, working channel 414 and its opening 410 are sterile. In some embodiments, the demagnetization electromagnet component 402 is positioned in proximity to opening 410 and/or working channel 414, for example wrapped around sterile opening 410 and/or working channel 414. In such embodiments, the tool 110 may be separated from the demagnetization electromagnet component 402 by sterile opening 410 and/or working channel 414, for example so as to prevent contact between the tool 110 and the demagnetization electromagnet component 402.

In some embodiments, the demagnetization can be electronically operated by a controller 404 such as an MCU or FPGA/ASIC inside the endoscope's handle or inside a robotic system or by an external host, or by any electrical circuitry. In some embodiments, the demagnetization can be powered using low voltage (for example, 1.5V, 3.3V, 5V) or high voltage (for example, 12V and above). In some embodiments, the demagnetization can be operated using an H-bridge with a square wave enabled signal. In some embodiments, the demagnetization can be fed from USB power (5V) or from MCU power (3.3V) or it can be battery powered or be powered by a robotic system power supply. In some embodiments, the demagnetization alternating field can be a sinusoidal field, or a square wave, or a triangular wave, or any other periodic or non-periodic strong alternating magnetic field, generated using an MCU, FPGA/ASIC, external host, simpler circuitry, H-bridge, or in any other suitable method.

In some embodiments, demagnetizing a tool 110 using the devices and methods described above is especially advantageous when sterility of the tool is required, such as in medical uses, since the disclosed devices and methods require no contact between the demagnetization devices with the tool.

### Exemplary Internal Demagnetization Device Located at The Sensors of Endoscopic Device

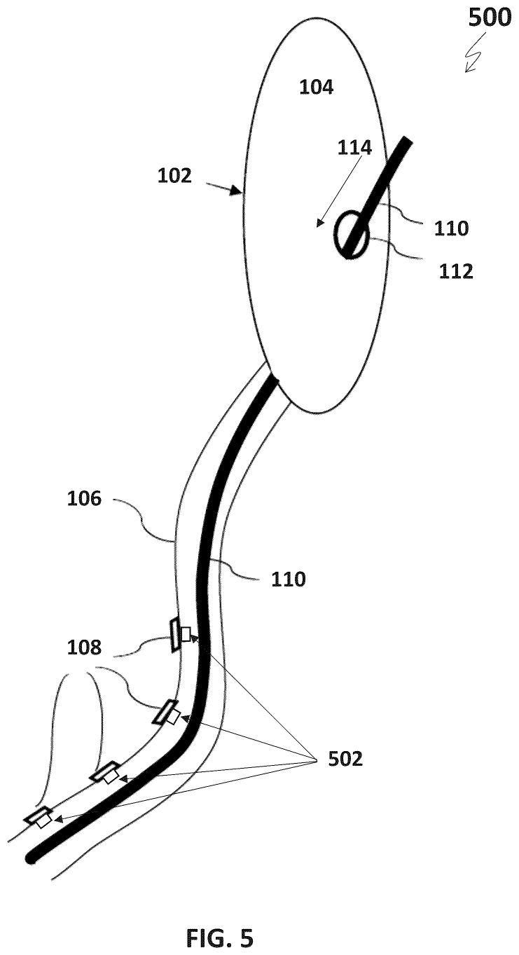

Referring now to FIG. 5, showing a schematic representation of an exemplary endoscopic device 500 comprising internal demagnetization devices, according to some embodiments of the invention. The endoscopic device 500 shown in FIG. 5 is similar to the endoscopic device 100 shown in FIG. 1, with the addition of a plurality of internal demagnetization devices 502 located under or adjacent the location of the sensors 108 used for position and orientation tracking of the endoscopic device. In some embodiments, the internal demagnetization devices 502 comprise an EM coil generating strong alternating magnetic fields which can be controlled for example by a controlling module. In some embodiments, the strong alternating magnetic fields can demagnetize any magnetized metal in proximity with the EM coils, which is suitable for demagnetizing the areas near the sensors where the internal demagnetization devices may be located. In some embodiments, this can be used, for example, to demagnetize the braid, pull-wires, links or any other magnetized metals of the endoscope at the areas of the EM sensors 108 as well as demagnetizing tool 110 which passes through the working channel at the area of the sensors 108. In some embodiments, the controlling module may use readings of the sensors 108 to detect magnetization of different areas of the endoscope as well as magnetization of introduced tool 110, additionally or alternatively to using dedicated sensors 214/218 (if found in the device). In some embodiments, the internal demagnetization devices 502 comprise an EM coil wrapped around a braided working channel of the endoscope, generating strong EM fields which are able to demagnetize both the braid as well as any tool passing through the working channel at the proximity of the EM coil. In other embodiments, the internal demagnetization devices 502 comprise an EM coil wrapped around each sensor, or next to each sensor and perpendicular to the working channel, generating strong EM fields perpendicular to the working channel which are also able to demagnetize both the braid as well as any tool passing through the working channel at the proximity of the EM coil.

In some embodiments, in the case where a Flexible Printed Circuit (FPC) is used, for example, in the case where EM sensors 108 are assembled on a Flexible Printed Circuit (FPC) and wrapped around the working channel 106, the same FPC can contain special traces which form EM coils at the proximity of each EM sensor, which can, for example, surround each EM sensor. Those traces can be driven by controlling module to generate strong alternating magnetic fields for demagnetization of the sensor sections, thus utilizing the same FPC between the sensors and the demagnetization coils.

In some embodiments, optionally, the internal demagnetization devices comprise a strong rotating permanent magnet (such as a Neodymium rare earth magnet) attached to a DC motor or oscillator. For example, in some embodiments, demagnetization is performed using a pair (2 or more) of strong permanent magnets (such as a Neodymium rare earth magnet) with opposite poles facing the working channel and moved near and far to the working channel using a DC motor or oscillator. In some embodiments, in this case, the internal demagnetization devices perform a dual role, on one side the internal demagnetization devices demagnetize the area around the sensors 108, thereby practically demagnetizing the endoscopic device (at least demagnetizing the required areas for the correct performance of the position and orientation tracking); while on the other side the internal demagnetization devices demagnetize any tool passing through the working channel in the vicinity of the sensors.

### Exemplary Demagnetization Electromagnet Configurations

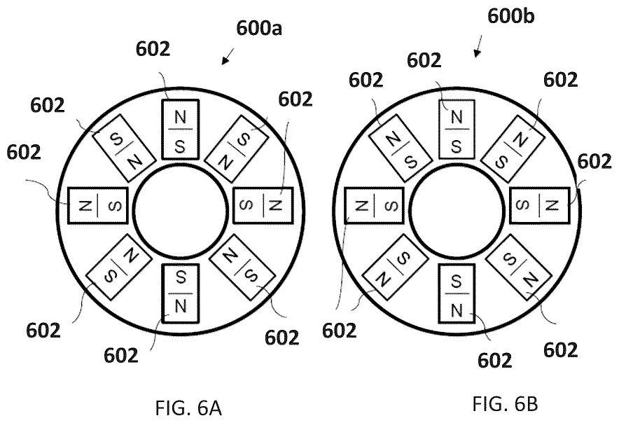

Referring now to FIGS. 6a-6b, showing schematic representations of exemplary demagnetization electromagnet configurations 600a and 600b respectively, according to some embodiments of the invention, which may be used as a demagnetization electromagnet component. In some embodiments, the demagnetization electromagnet configurations 600a and 600b comprise a set of small permanent magnets 602, for example permanent magnet dipoles, for example, rare-earth magnets, placed in a specific configuration. For example, in some embodiments, demagnetization electromagnet configuration 600a may include several, for example 4-8, permanent magnets 602, for example positioned in alternating polarity: N, S, N, S, etc. In some embodiments, permanent magnets 602 may be mechanically fixed in proximity to the opening 208/410 and/or working channel 106/414. In some embodiments, as tool 110 passes through working channel 106/414, it may experience strong magnetic fields in alternating polarities, which magnetize different sections along the perimeter of tool 110 in different polarities. In some embodiments, the net cross-section magnetization of tool 110 can then become approximately zero due to the alternating magnetization polarity of the tool's perimeter.

In some embodiments, a potential advantage of using permanent magnets 602 in demagnetization electromagnet configuration 600a instead of electromagnetic coils is that it can potentially simplify the demagnetization process, as no electrical circuit and/or controller is needed. In some embodiments, this can potentially reduce the costs of the demagnetization component in an endoscope which is potentially advantageous for example in the setting of a disposable endoscope.

In some embodiments, alternatively, a demagnetization electromagnet configuration 600b may include several, permanent magnets 602, for example oriented similarly relative to the axis of the inserted tool (for example, all dipoles oriented with South pole pointing towards the center of the inserted tool).

In some embodiments, alternatively, all permanent magnets 602 are aligned with the axis of the inserted tool (for example, all dipoles oriented with South pole pointing in the direction of the axis of the inserted tool). In some embodiments, the magnetic dipoles can be aligned with the axis of the inserted tool but can have alternating polarity (N, S, N, S, etc.).

In some embodiments, alternatively, the demagnetization device 200 and/or the demagnetization electromagnet component 302 and/or the demagnetization electromagnet component 402 include a rotating magnet, to generate a strong alternating magnetic field for demagnetization—as shown for example in FIG. 4. In some embodiments, one or more magnets, such as rare-earth magnets 418, are mounted on rotating axes, for example, of a brush or brushless motor 420. In some embodiments, the motor and magnets can be miniaturized to fit inside a handle of an endoscope (for example, such as handle 104) or a robotic endoscope's interface 408, or they can potentially be larger and placed in the robotic mount at the proximity of working channel 414. In some embodiments, using a rotating magnet has the potential advantage of generating a strong alternating magnetic field with rather low power consumption (for example, with less than 100 mW power consumption), where the power is only consumed by the rotating motor (and not by the generation of a strong magnetic field).

In some embodiments, instead of using permanent magnets, demagnetization electromagnet configuration 600a-b can comprise small magnetic coils which can optionally be wrapped around a magnetic core and/or shielded by a high magnetic permeability shield to amplify the generated field. In this case, each magnetic coil can then be controlled and activated using a microcontroller. In some embodiments, the dipole direction can also be controlled by the microcontroller. In some embodiments, the microcontroller can then generate any configuration of magnetic dipole orientations for in the magnetic coils surrounding the working channel. In some embodiments, the microcontroller can also generate an alternating magnetic field as described above. In some embodiments, using electromagnetic coils instead of permanent magnets allows greater control over the generated magnetic field surrounding the inserted tool, according to some embodiments of the present disclosure.

In some embodiments, demagnetization electromagnet configuration can comprise electromagnetic coils which are wrapped inside a robotic system, near or inside the robotic interface with a mounted robotic endoscope. In some embodiments, the generated demagnetization fields may then act on an introduced working channel tool through the robotic interface to demagnetize it while it's being introduced. In some embodiments, the electromagnetic coils may reside inside the robotic endoscope, and may interface with an electrical current-driving mechanism which resides inside the robotic system.

### EXEMPLARY METHODS

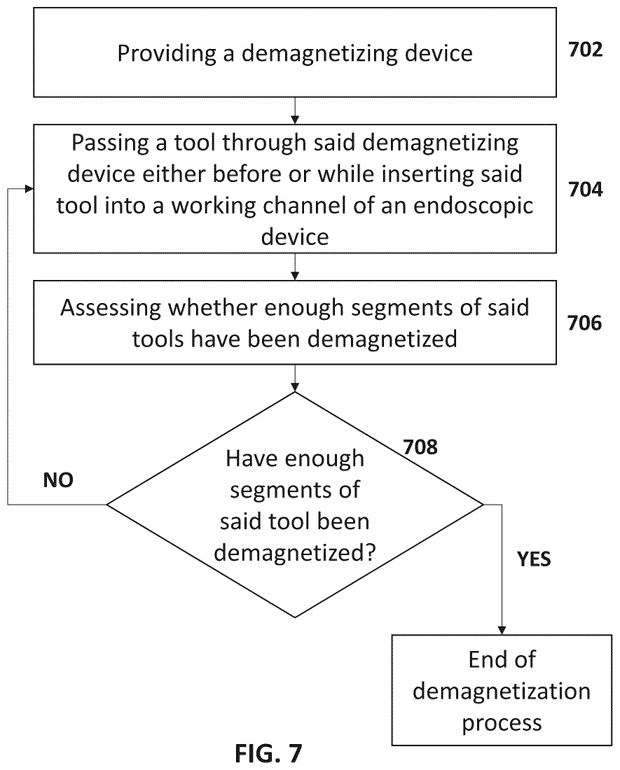

Referring now to FIG. 7, showing a flowchart of an exemplary method of demagnetizing a tool according to some embodiments of the invention. In some embodiments, exemplary actions to be performed to demagnetize a tool comprise one or more of:
1. Providing a demagnetization device (702);
2. Passing a tool through said demagnetization device (704).

In some embodiments, the passing is performed either before or while inserting said tool into a working channel of an endoscopic device. In some embodiments, the demagnetizing comprises applying an alternating magnetic field along the tool, optionally a strong alternating magnetic field.
3. Assessing whether enough segments of the tool have been demagnetized (706).
4. The system is configured to wait for a response (708):

If the answer is NO, then the method returns to point 704, which is passing the tool through the demagnetizer.

If the answer is YES, then the method ends.

### ADDITIONAL INFORMATION

In some embodiments, the tracked length of the endoscope may be demagnetized prior to procedure in a factory demagnetization step. In this case, the tracked length of the endoscope is placed in or passed through a demagnetization device, such as demagnetization device 200 to ensure that the tracked length is demagnetized. In some embodiments, the endoscope is then shipped carefully to avoid further demagnetization of the device (for example, keeping magnetized objects far from the shipped endoscope) such that it will be demagnetized and ready for operation in procedure.

In some embodiments, in order to make sure that the tracked length of the endoscope is demagnetized, a controller may read the sensed magnetic values from all sensing elements. The controller may be the same controller which reads the magnetic values from the sensing elements to perform the tracking. If the controller detects high magnetic bias for certain sensing elements (for example, stronger than 500 uT), as reported by the magnetic readings of those sensing elements (for example, digital magnetometer sensors) then these elements are detected as magnetized sensor elements and further demagnetization needs to be applied in or prior to procedure, for example, using demagnetization device 200 or using other demagnetization methods, or the endoscope needs to be disposed and replaced. By reading the magnetic bias from all sensor elements the controller can ensure that the device is demagnetized and ready for use in procedure.

In some embodiments, if only a few sensors are detected to be magnetized then the tracker may ignore those sensors, or rely more on others (potentially neighboring) sensors in a combined curve tracking algorithm of the device. For example, in one such algorithm a curve will be fitted through all tracked sensors but with zero or smaller weights for sensors which are detected as magnetized, or with weights which decrease in accordance with magnetization (the stronger the magnetization, the smaller are the weights).

In another embodiment, an external dedicated demagnetization device may be used to demagnetize the endoscope's tracked section in case that it is fully or partially magnetized, as can be measured by the sensor elements. In case that some of the sensors are magnetized, the user is instructed to place the endoscope's tracked section in a demagnetizer device such as demagnetizer device 200, or in another demagnetizer device, which can be for example part of a robotic system or a dedicated demagnetizer device. For example, a robotic system may contain a sterile hole (orifice) into which a magnetized endoscope can be inserted which contains demagnetization electromagnet component which demagnetizes the inserted endoscope's tracked section.

In another embodiment, a robotic interface mechanism may contain a demagnetizer device inside the interface which is part of the robotic system. Prior to procedure, a physician may place the endoscope's distal tracked length close to the robotic interface and the demagnetizer can then be manually or automatically activated.

The demagnetizer may be powerful enough to allow zero-contact demagnetization of the endoscope's tracked section, for example, at distance less than 1 cm or 2 cm or 5 cm or 10 cm or 20 cm of the endoscope's tracked length from the robotic demagnetizer. A zero-contact demagnetizer is beneficial to preserve sterility of the endoscope. In another embodiment, a demagnetizer can be located in different places in a robotic or manual tracking system, to allow for demagnetizing of the endoscope's tracked length with zero-contact or sterile contact. For example, the endoscope can be demagnetized while still being packaged, since no contact is required for the demagnetization.

In some embodiment, prior or during procedure, the endoscope's tracked length may be detected as magnetized, for example, by one or more sensing elements which may sense high magnetic bias in their magnetic readings. In this case the physician may pull the endoscope out from the patient, or the endoscope can be pulled automatically by a robotic driving mechanism, and hold the endoscope's tracked length in the proximity of a zero-contact demagnetizer, which may be located inside a robotic system, for example, near or inside a robotic interface, driving mechanism or cart, or can be a dedicated zero-contact demagnetizer in the case of a manual endoscope or can have any other configuration which perform demagnetization of the endoscope's tracked length while preserving the endoscope's sterility.

In another embodiment, the robotic system may contain a demagnetizer device, or a demagnetization electromagnet component such that when the endoscope is loaded to the robot, the demagnetizer is positioned in proximity to the endoscope's tracked section and is activated automatically, for example, based on magnetic bias reading by the endoscope's sensor elements, demagnetizing the endoscope's tracked length automatically. The robotic demagnetizer may be located near the endoscope's tracked length, for example, inside or around a robotic endoscope guiding/support sleeve such that the endoscope's tracked section is passed through or near the robotic demagnetizer.

In some embodiments, the endoscope may pass through or in proximity of the demagnetizer multiple times based on the effectiveness of the robotic demagnetizer, as sensed by the endoscope's sensing elements (which can be magnetometer sensors) until the endoscope's tracked length is fully or partially demagnetized to a satisfactory level.

In some embodiments, in the case of tool demagnetization (such as tool 110) the tool can be made of non-magnetic materials, such as tungsten, titanium, nitinol, Kevlar or other non-magnetic materials, to prevent the tool from being magnetized, or to reduce the magnetization of the tool, and thus potentially eliminating or reducing magnetic interference (such as undesirable bias or saturation) on the sensors tracking the endoscopic device.

In some embodiments, only the section of the tool where it coincides with the endoscope's tracked section can be made of non-magnetic materials, for example, the tool's distal 200 mm or 250 mm or 300 mm or 350 mm, such that when the tool is partially or fully inserted into the manual/robotic endoscope, or even inserted through the endoscope and protruding a certain length out of the distal end of the endoscope only the tool's non-magnetic section (for example, the tool's distal 300 mm) will coincide with the endoscope's tracked section (for example, the endoscope's distal 200 mm).

As used herein with reference to quantity or value, the term “about” means “within±10 % of”.

The terms “comprises”, “comprising”, “includes”, “including”, “has”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular forms “a”, “an” and “the” include plural references unless the context clearly dictates otherwise. For example, the term “a compound” or “at least one compound” may include a plurality of compounds, including mixtures thereof.

Throughout this application, embodiments of this invention may be presented with reference to a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as “from 1 to 6” should be considered to have specifically disclosed subranges such as “from 1 to 3”, “from 1 to 4”, “from 1 to 5”, “from 2 to 4”, “from 2 to 6”, “from 3 to 6”, etc.; as well as individual numbers within that range, for example, 1, 2, 3, 4, 5, and 6. This applies regardless of the breadth of the range.

Whenever a numerical range is indicated herein (for example “10-15”, “10 to 15”, or any pair of numbers linked by these another such range indication), it is meant to include any number (fractional or integral) within the indicated range limits, including the range limits, unless the context clearly dictates otherwise. The phrases “range/ranging/ranges between” a first indicate number and a second indicate number and “range/ranging/ranges from” a first indicate number “to”, “up to”, “until” or “through” (or another such range-indicating term) a second indicate number are used herein interchangeably and are meant to include the first and second indicated numbers and all the fractional and integral numbers therebetween.

Unless otherwise indicated, numbers used herein and any number ranges based thereon are approximations within the accuracy of reasonable measurement and rounding errors as understood by persons skilled in the art.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. A device configured for demagnetizing a tool adapted to be inserted in a working channel of an endoscope, the device comprising:
a. a body comprising an orifice; and
b. an electromagnet component positioned at a proximity to said orifice.

2. The device according to claim 1, further comprising circuitry configured for generating a magnetic field by said electromagnet component.

3. The device according to claim 1, wherein said body further comprises a handle.

4. The device according to claim 1, wherein said orifice is sized and shaped for receiving therein said working channel of said endoscope.

5. The device according to claim 1, wherein said electromagnet component comprises a motor and a rotating permanent magnet attached to said motor.

6. The device according to claim 1, wherein said electromagnet component is configured for generating a demagnetization electromagnetic field frequency of 10 kHz or below.

7. The device according to claim 1, wherein said electromagnet component comprises one or more electromagnetic coils.

8. The device according to claim 1, wherein said electromagnet component is positioned parallel and/or around to said orifice_and/or perpendicular to said orifice.

9. (canceled)

10. The device according to claim 1, wherein said electromagnet component is configured for generating a magnetic field having an amplitude of about 100 mT or below, 1 T or below, or 10 T or below.

11. The device according to claim 1, wherein said device further comprises at least one sensor configured for sensing a magnetic field of said tool;
wherein said at least one sensor is a magnetometer sensor; and
wherein said at least one sensor is positioned at a proximity of said orifice.

12-13. (canceled)

14. The device according to claim 1, wherein said device further comprises an indicator;
wherein said circuitry is further configured for activating said indicator; and
wherein said indicator is configured for indicating whether a demagnetization process was successful or not.

15-16. (canceled)

17. The device according to claim 1, further comprising one or more motors configured for engaging said tool and further configured for moving said tool within said orifice during a demagnetization process; and wherein said circuitry is further configured for controlling said one or more motors.

18. (canceled)

19. The device according to claim 1, wherein said device further comprises a shutter/valve at said orifice and configured for engaging said tool.

20. The device according to claim 1, wherein said device further comprises at least one additional sensor configured for sensing a magnetic field of said tool after said tool has passed through said electromagnet component.

21. The device according to claim 1, wherein the demagnetization electromagnet configuration includes a set of small permanent magnets positioned in alternating polarity, or oriented similarly relative to the axis of the inserted tool, or aligned with the axis of the inserted tool.

22. A method of demagnetizing a tool adapted to be inserted in a working channel of an endoscope, the method comprising passing said tool through a demagnetizer.

23. The method according to claim 22, further comprising activating said demagnetizer while passing said tool through an orifice in said demagnetizer.

24. The method according to claim 23, wherein said activating said demagnetizer is performed while inserting said tool in said working channel.

25. The method according to claim 23, wherein said activating said demagnetizer comprises applying a strong alternating magnetic field along said tool.

26. The method according to claim 22, further comprising assessing whether enough segments of said tool have been demagnetized;
wherein if an answer is NO, then the method further comprises re-passing said tool through said demagnetizer; and
wherein if an answer is YES, then the method ends.

27-63. (canceled)
